(19) United States
(12) Patent Application Publication
(10) Pub. No.: US 2024/0243697 A1
(43) Pub. Date: Jul. 18, 2024

(54) TRACKER MODULE

(71) Applicant: Murata Manufacturing Co., Ltd., Nagaokakyo-shi (JP)

(72) Inventors: Takanori UEJIMA, Nagaokakyo-shi (JP); Masanari MIURA, Nagaokakyo-shi (JP); Takeshi KOGURE, Nagaokakyo-shi (JP)

(21) Appl. No.: 18/619,853

(22) Filed: Mar. 28, 2024

Related U.S. Application Data
(63) Continuation of application No. PCT/JP2022/035998, filed on Sep. 27, 2022.

(30) Foreign Application Priority Data
Oct. 11, 2021 (JP) 2021-166755

(51) Int. Cl. H03F 1/02; H03F 3/24

(52) U.S. Cl. CPC H03F 1/02; H03F 3/24

(57) ABSTRACT

A tracker module is provided that includes a module laminate, an integrated circuit disposed on the module laminate, and a power inductor disposed on the module laminate. The integrated circuit includes at least one switch included in a pre-regulator circuit that converts an input voltage into a first voltage using the power inductor, at least one switch included in a switched-capacitor circuit that generates a plurality of discrete voltages from the first voltage, and at least one switch included in a supply modulator that selectively outputs, based on an envelope signal, at least one of the plurality of discrete voltages.

### CROSS REFERENCE TO RELATED APPLICATIONS

This application is a continuation of International Application No. PCT/JP2022/035998, filed Sep. 27, 2022, which claims priority to Japanese Patent Application No. 2021-166755, filed Oct. 11, 2021, the entire contents of each of which are hereby incorporated by reference in their entirety.

### TECHNICAL FIELD

The present disclosure relates to a tracker module.

### BACKGROUND

U.S. Pat. No. 9,755,672 (hereinafter “Patent Document 1”) discloses a power supply modulator circuit that can supply a power supply voltage dynamically adjusted over time in accordance with a radio frequency signal to a power amplifier.

The power supply modulator circuit (e.g., a power supply circuit) in Patent Document 1 includes a magnetic regulation stage (e.g., a pre-regulator circuit) that adjusts a direct current voltage using a power inductor. In making the power supply circuit as a module, deterioration of electrical characteristics or electromagnetic interference (EMI) caused by noise needs to be addressed.

### SUMMARY OF THE INVENTION

In view of the foregoing, the exemplary aspects of the present disclosure provide a tracker module that suppresses deterioration of characteristics and/or EMI caused by noise.

In an exemplary aspect, a tracker module is provided that includes a module laminate, at least one integrated circuit disposed on the module laminate, and a power inductor disposed on the module laminate. The at least one integrated circuit includes at least one switch included in a pre-regulator circuit that is configured to convert an input voltage into a first voltage using the power inductor, at least one switch included in a switched-capacitor circuit that is configured to generate a plurality of discrete voltages based on the first voltage, and at least one switch included in a supply modulator that is configured to selectively output at least one of the plurality of discrete voltages based on an envelope signal.

In another exemplary aspect, a tracker module is provided that includes a module laminate, at least one integrated circuit disposed on the module laminate, and a power inductor disposed on the module laminate. The at least one integrated circuit includes at least one switch included in a pre-regulator circuit that is configured to convert an input voltage into a first voltage using the power inductor, at least one switch included in a switched-capacitor circuit that is configured to generate a plurality of discrete voltages from the first voltage, and at least one switch included in a supply modulator that includes a control terminal connected to a control circuit and that is configured to selectively output at least one of the plurality of discrete voltages.

In yet another exemplary aspect, a tracker module is provided that includes a module laminate, at least one integrated circuit disposed on the module laminate, and a power inductor disposed on the module laminate. The at least one integrated circuit includes at least one switch included in a pre-regulator circuit, at least one switch included in a switched-capacitor circuit, and at least one switch included in a supply modulator. The switched-capacitor circuit includes a first capacitor including a first electrode and a second electrode, and a second capacitor including a third electrode and a fourth electrode. The at least one switch included in the switched-capacitor circuit includes a first switch, a second switch, a third switch, a fourth switch, a fifth switch, a sixth switch, a seventh switch, and an eighth switch. A first end of the first switch and a first end of the third switch are connected to the first electrode. A first end of the second switch and a first end of the fourth switch are connected to the second electrode. A first end of the fifth switch and a first end of the seventh switch are connected to the third electrode. A first end of the sixth switch and a first end of the eighth switch are connected to the fourth electrode. The second end of the first switch, the second end of the second switch, the second end of the fifth switch, and the second end of the sixth switch are connected to each other. The second end of the third switch is connected to the second end of the seventh switch. The second end of the fourth switch is connected to the second end of the eighth switch. The supply modulator includes an output terminal. The at least one switch included in the supply modulator includes a ninth switch connected between the output terminal and the second ends of the first switch, the second switch, the fifth switch, and the sixth switch, and a tenth switch connected between the output terminal and the second ends of the third switch and the seventh switch. The pre-regulator circuit includes the power inductor and an input terminal. The at least one switch included in the pre-regulator circuit includes an eleventh switch connected between the input terminal and a first end of the power inductor, and a twelfth switch connected between the first one end of the power inductor and a ground. The second end of the power inductor is connected to the second ends of the first switch, the second switch, the fifth switch, and the sixth switch.

According to the exemplary aspects of tracker module in the present disclosure, deterioration of characteristics and/or EMI caused by noise are suppressed.

### BRIEF DESCRIPTION OF DRAWINGS

FIG. 1 is a circuit configuration diagram of a communication device according to an exemplary embodiment.

FIG. 2 is a circuit configuration diagram of a pre-regulator circuit, a switched-capacitor circuit, supply modulators, and filter circuits according to the exemplary embodiment.

FIG. 3A is a graph illustrating a power supply voltage supplied by digital envelope tracking.

FIG. 3B is a graph illustrating a power supply voltage supplied by analog envelope tracking.

FIG. 4 is a plan view of a tracker module according to a first exemplary aspect.

FIG. 5 is a plan view of the tracker module according to the first exemplary aspect.

FIG. 6 is a sectional view of the tracker module according to the first exemplary aspect.

FIG. 7 is a sectional view of the tracker module according to the first exemplary aspect.

FIG. 8 is a plan view of a tracker module according to a second exemplary aspect.

FIG. 9 is a sectional view of the tracker module according to the second exemplary aspect.

FIG. 10 is a plan view of a tracker module according to a third exemplary aspect.

FIG. 11 is a plan view of a tracker module according to a fourth exemplary aspect.

FIG. 12 is a plan view of a tracker module according to a fifth exemplary aspect.

FIG. 13 is a sectional view of a tracker module according to another exemplary aspects.

### DETAILED DESCRIPTION

Hereinafter, an exemplary embodiment of the present disclosure will be described in detail using the drawings. Any embodiment described below illustrates a comprehensive or specific example. Numerical values, shapes, materials, constituents, a disposition and a connection form of the constituents, and the like illustrated in the following embodiment are examples and not intended to limit the exemplary embodiments.

It is noted that each drawing is a schematic diagram that is highlighted, omitted, or adjusted in ratio, as appropriate, to illustrate the exemplary embodiments of the present disclosure and is not necessarily illustrated in a strict sense. Each drawing may have different shapes, positional relationships, and ratios from those in actuality. Substantially the same configurations are designated by the same reference signs in each drawing, and duplicate descriptions may be omitted or simplified.

In each drawing below and for purposes of this disclosure, an x axis and a y axis are axes that are orthogonal to each other on a plane parallel to a main surface of a module laminate. Specifically, in a case where the module laminate has a rectangular shape in a plan view, the x axis is parallel to a first edge of the module laminate, and the y axis is parallel to a second edge of the module laminate that is orthogonal to the first edge. In addition, a z axis is an axis perpendicular to the main surface of the module laminate. A positive direction of the z axis indicates an upward direction, and a negative direction of the z axis indicates a downward direction.

In a circuit configuration of the present disclosure, the term “connected” includes not only a case of being directly connected through a connection terminal and/or a wire conductor but also a case of being electrically connected through other circuit elements. Moreover, the expression “connected between A and B” means connection to both of A and B between A and B and includes, in addition to series connection to a path connecting A to B, parallel connection (e.g., a shunt connection) between the path and a ground.

In component disposition of the present disclosure, the expression “a component is disposed on a laminate” includes a case where the component is disposed on a main surface of the laminate, and a case where the component is disposed in the laminate. Moreover, the expression “the component is disposed on the main surface of the laminate” includes, in addition to a case where the component is disposed in contact with the main surface of the laminate, a case where the component is disposed above the main surface without being in contact with the main surface (for example, another component disposed in contact with the main surface is laminated with the component). In addition, the expression “the component is disposed on the main surface of the laminate” may include a case where the component is disposed in a recessed portion formed on the main surface. The expression “the component is disposed in the laminate” includes, in addition to a case where the component is encapsulated in the module laminate, a case where the entire component is disposed between both main surfaces of the laminate and a part of the component is not covered with the laminate, and a case where only a part of the component is disposed in the laminate.

In addition, in the component disposition of the present disclosure, the expression “plan view of the module laminate” means viewing an object orthogonally projected to an xy plane from a positive side of the z axis. Moreover, the expression “A overlaps B in plan view” means that a region of A orthogonally projected to the xy plane overlaps a region of B orthogonally projected to the xy plane.

In addition, in the component disposition of the present disclosure, the expression “A is disposed adjacent to B” means that A and B are disposed close to each other and specifically means that another circuit component is not present in a space in which A faces B. In other words, the expression “A is disposed adjacent to B” means that any of a plurality of line segments that reach B along a direction normal to a surface of A facing B from any point on the surface does not pass through a circuit component other than A and B. Here, the circuit component means a component including an active element and/or a passive element. That is, the circuit component includes an active component including a transistor, a diode, or the like and a passive component including an inductor, a transformer, a capacitor, a resistor, or the like and does not include an electromechanical component including a terminal, a connector, a wire, or the like.

In addition, in the component disposition of the present disclosure, the expression “C is disposed closer to A than B is” means that a distance between A and C is shorter than a distance between A and B. Here, the expression “the distance between A and B” means the shortest distance between A and B. That is, the expression “the distance between A and B” means a length of the shortest line segment among a plurality of line segments connecting any point on the surface of A to any point on a surface of B.

In addition, terms such as “parallel” and “perpendicular” indicating a relationship between elements, terms such as “rectangular” indicating a shape of an element, and numerical value ranges not only represent a strict meaning, but also mean that a substantially equivalent range including, for example, an error of approximately a few % is included.

### Exemplary Embodiment

Hereinafter, a tracker module and a communication device according to the present embodiment will be described with reference to the drawings.

### [1 Circuit Configurations of Communication Device 7 and Power Supply Circuit 1]

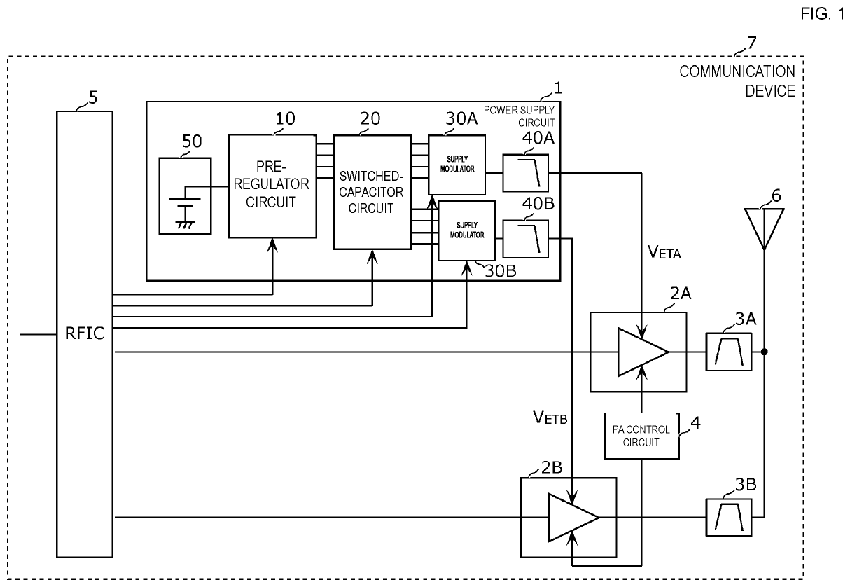

A circuit configuration of a communication device 7 according to the present embodiment will be described with reference to FIG. 1. FIG. 1 is a circuit configuration diagram of the communication device 7 according to the present embodiment.

### [1.1 Circuit Configuration of Communication Device 7]

First, the circuit configuration of the communication device 7 will be described. As illustrated in FIG. 1, the communication device 7 according to the present embodiment includes a power supply circuit 1, power amplifiers (PA) 2A and 2B, filters 3A and 3B, a PA control circuit 4, a radio frequency integrated circuit (RFIC) 5, and an antenna 6.

The power supply circuit 1 can supply power supply voltages V_{ETA} and V_{ETB} to the power amplifiers 2A and 2B, respectively, in a digital envelope tracking (ET) mode. In the digital ET mode, a voltage level of each of the power supply voltages V_{ETA} and V_{ETB} is selected, from a plurality of discrete voltage levels, based on a digital control signal corresponding to an envelope signal and changes over time.

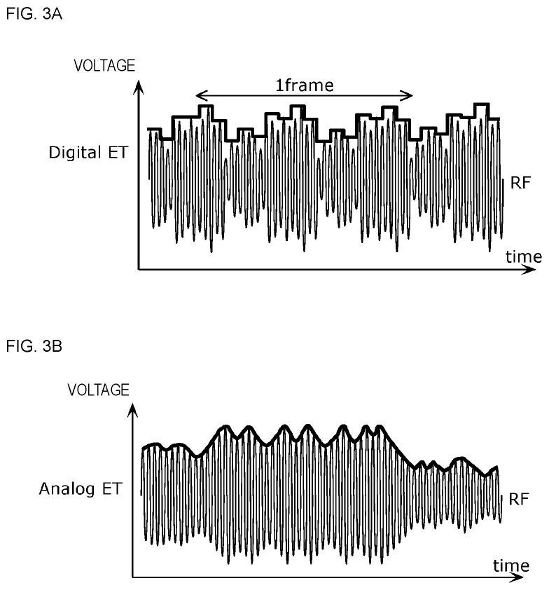

The envelope signal is a signal indicating an envelope value of a modulated signal (e.g., a radio frequency signal). The envelope value is represented by, for example, a square root of (I₂+Q₂). Here, (I, Q) represents a constellation point. The constellation point is a point representing a signal modulated by digital modulation on a constellation diagram. Details of the digital ET mode will be described later using FIGS. 3A and 3B.

While the power supply circuit 1 supplies the two power supply voltages V_{ETA} and V_{ETB} to the two power amplifiers 2A and 2B, respectively, in FIG. 1, the power supply circuit 1 may supply the same power supply voltage to a plurality of power amplifiers. In addition, the power supply circuit 1 may supply a power supply voltage to only one power amplifier.

As illustrated in FIG. 1, the power supply circuit 1 includes a pre-regulator circuit 10, a switched-capacitor circuit 20, supply modulators 30A and 30B, filter circuits 40A and 40B, and a direct current power source 50.

The pre-regulator circuit 10 includes a power inductor and a switch. The power inductor is an inductor used for stepping up and/or stepping down a direct current voltage. The power inductor is disposed in series on a direct current path. The power inductor may be connected (e.g., in parallel) between a series path and the ground. The pre-regulator circuit 10 can convert an input voltage into a first voltage using the power inductor. The pre-regulator circuit 10 maybe referred to as a magnetic regulator or a direct current (DC)/DC converter.

The switched-capacitor circuit 20 includes a plurality of capacitors and a plurality of switches. The switched-capacitor circuit 20 can generate a plurality of second voltages having the plurality of respective discrete voltage levels as a plurality of discrete voltages from the first voltage from the pre-regulator circuit 10. The switched-capacitor circuit 20 maybe referred to as a switched-capacitor voltage balancer in an exemplary aspect.

The supply modulators 30A and 30B can select one of the plurality of second voltages generated by the switched-capacitor circuit 20 and output the selected voltage to the filter circuits 40A and 40B, respectively, based on the digital control signal corresponding to the envelope signal.

The filter circuits 40A and 40B can filter signals (e.g., second voltages) from the supply modulators 30A and 30B.

The direct current power source 50 can supply a direct current voltage to the pre-regulator circuit 10. For example, a rechargeable battery can be used as the direct current power source 50. However, the exemplary aspects are not limited thereto.

In particular, the power supply circuit 1 may not include at least one of the pre-regulator circuit 10, the switched-capacitor circuit 20, the supply modulators 30A and 30B, the filter circuits 40A and 40B, and the direct current power source 50. For example, when the power supply voltage is supplied to only one power amplifier, the power supply circuit 1 may include neither the supply modulator 30B nor the filter circuit 40B. In addition, the power supply circuit 1 may not include the direct current power source 50 or the power supply circuit 1 may not include the filter circuits 40A and 40B. In addition, any combination of the pre-regulator circuit 10, the switched-capacitor circuit 20, the supply modulators 30A and 30B, and the filter circuits 40A and 40B may be integrated into a single circuit.

The power amplifier 2A is connected between the RFIC 5 and the filter 3A. Furthermore, the power amplifier 2A can receive the power supply voltage V_{ETA} from the power supply circuit 1 and can receive a bias signal from the PA control circuit 4. Accordingly, the power amplifier 2A can amplify a transmission signal of a band A received from the RFIC 5.

The power amplifier 2B is connected between the RFIC 5 and the filter 3B. Furthermore, the power amplifier 2B can receive the power supply voltage V_{ETB} from the power supply circuit 1 and can receive the bias signal from the PA control circuit 4. Accordingly, the power amplifier 2B can amplify a transmission signal of a band B received from the RFIC 5.

The filter 3A is connected between the power amplifier 2A and the antenna 6. The filter 3A has a passband including the band A. Accordingly, the transmission signal of the band A amplified by the power amplifier 2A can pass through the filter 3A.

The filter 3B is connected between the power amplifier 2B and the antenna 6. The filter 3B has a passband including the band B. Accordingly, the transmission signal of the band B amplified by the power amplifier 2B can pass through the filter 3B.

The PA control circuit 4 can control the power amplifiers 2A and 2B. Specifically, the PA control circuit 4 can supply the bias signal to each of the power amplifiers 2A and 2B.

The RFIC 5 is an example of a signal processing circuit that processes a radio frequency signal. Specifically, the RFIC 5 is configured to perform signal processing, such as upconversion, on an input transmission signal and supplies the radio frequency transmission signal generated through the signal processing to the power amplifiers 2A and 2B. In addition, the RFIC 5 includes a control unit that controls the power supply circuit 1. A part or all of functions of the RFIC 5 as the control unit may be mounted outside the RFIC 5.

The antenna 6 transmits the signal of the band A input from the power amplifier 2A through the filter 3A and the signal of the band B input from the power amplifier 2B through the filter 3B.

In general, bands A and B are frequency bands for a communication system constructed using a radio access technology (RAT). The bands A and B are defined in advance by standardizing bodies (for example, 3rd Generation Partnership Project (3GPP)®, Institute of Electrical and Electronics Engineers (IEEE), and the like). Examples of the communication system include a 5th Generation New Radio (5G NR) system, a Long Term Evolution (LTE) system, and a wireless local area network (WLAN) system.

It should be appreciated that the circuit configuration of the communication device 7 illustrated in FIG. 1 is an example, and should not limited thereto. For example, the communication device 7 may not include the antenna 6 in an alternative aspect. Instead, for example, the communication device 7 may include a plurality of antennas, for example.

### [1.2 Circuit Configuration of Power Supply Circuit 1]

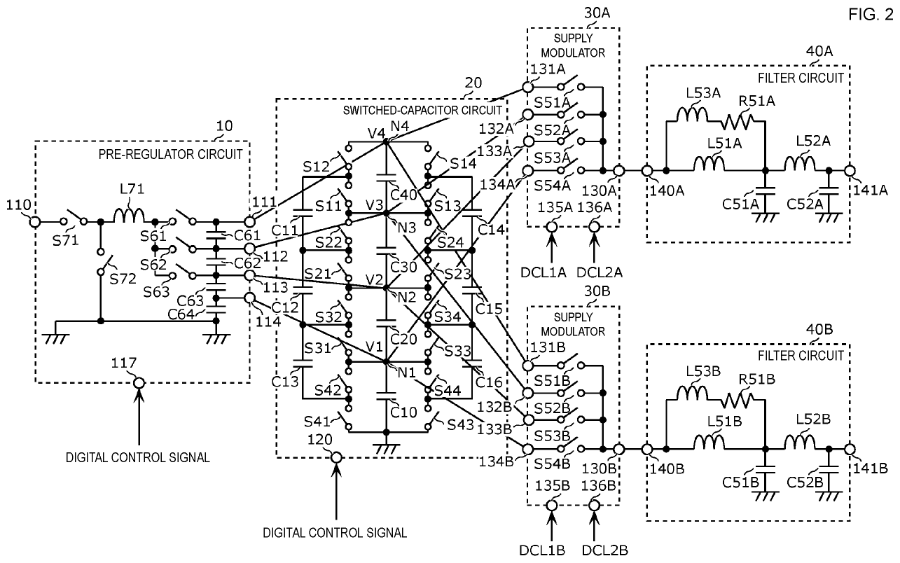

Next, circuit configurations of the pre-regulator circuit 10, the switched-capacitor circuit 20, the supply modulators 30A and 30B, and the filter circuits 40A and 40B included in the power supply circuit 1 will be described with reference to FIG. 2. FIG. 2 is a circuit configuration diagram of the pre-regulator circuit 10, the switched-capacitor circuit 20, the supply modulators 30A and 30B, and the filter circuits 40A and 40B according to the present embodiment.

FIG. 2 is an exemplary circuit configuration, and the pre-regulator circuit 10, the switched-capacitor circuit 20, the supply modulators 30A and 30B, and the filter circuits 40A and 40B may be mounted using any of various circuit mounting methods and circuit technologies. Accordingly, description of each circuit provided below is not to be interpreted as being limiting.

### [1.2.1 Circuit Configuration of Switched-Capacitor Circuit 20]

First, the circuit configuration of the switched-capacitor circuit 20 will be described. As illustrated in FIG. 2, the switched-capacitor circuit 20 includes capacitors C11 to C16, capacitors C10, C20, C30, and C40, switches S11 to S14, S21 to S24, S31 to S34, and S41 to S44, and a control terminal 120. Energy and charges are input into the switched-capacitor circuit 20 from the pre-regulator circuit 10 in nodes N1 to N4 and are output to the supply modulators 30A and 30B from the switched-capacitor circuit 20 in the nodes N1 to N4.

The control terminal 120 is an input terminal of the digital control signal. That is, the control terminal 120 is a terminal for receiving the digital control signal for controlling the switched-capacitor circuit 20. For example, a control signal of a source-synchronous scheme for transmitting a data signal and a clock signal can be used as the digital control signal received through the control terminal 120. However, the exemplary aspects of present disclosure are not limited thereto. For example, a control signal of a clock-embedded scheme in which a clock is embedded in a data signal may be used as the digital control signal.

Each of the capacitors C11 to C16 can be configured to function as a flying capacitor (also referred to as a transfer capacitor). That is, each of the capacitors C11 to C16 is used for stepping up or stepping down the first voltage supplied from the pre-regulator circuit 10. More specifically, the capacitors C11 to C16 cause charges to move between the capacitors C11 to C16 and the nodes N1 to N4 such that voltages V1 to V4 (voltages with respect to a ground potential) satisfying V1:V2:V3:V4=1:2:3:4 are maintained in the four nodes N1 to N4. The voltages V1 to V4 correspond to the plurality of second voltages having the plurality of respective discrete voltage levels.

The capacitor C11 includes two electrodes. One of the two electrodes of the capacitor C11 is connected to one end of the switch S11 and one end of the switch S12. The other of the two electrodes of the capacitor C11 is connected to one end of the switch S21 and one end of the switch S22. For purposes of this disclosure the term “one end” may generally be considered a “first end” and the term “another end” or the “other end” may generally be considered a “second end”. These terms for such components may be interchangeable as would be appreciated to one skilled in the art.

The capacitor C12 is an example of a first capacitor and includes two electrodes (examples of a first electrode and a second electrode). One of the two electrodes of the capacitor C12 is connected to the one end of the switch S21 and the one end of the switch S22. The other of the two electrodes of the capacitor C12 is connected to one end of the switch S31 and one end of the switch S32.

The capacitor C13 includes two electrodes. One of the two electrodes of the capacitor C13 is connected to the one end of the switch S31 and the one end of the switch S32. The other of the two electrodes of the capacitor C13 is connected to one end of the switch S41 and one end of the switch S42.

The capacitor C14 includes two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 is an example of a second capacitor and includes two electrodes (examples of a third electrode and a fourth electrode). One of the two electrodes of the capacitor C15 is connected to the one end of the switch S23 and the one end of the switch S24. The other of the two electrodes of the capacitor C15 is connected to one end of the switch S33 and one end of the switch S34.

The capacitor C16 includes two electrodes. One of the two electrodes of the capacitor C16 is connected to the one end of the switch S33 and the one end of the switch S34. The other of the two electrodes of the capacitor C16 is connected to one end of the switch S43 and one end of the switch S44.

Each of a set of the capacitors C11 and C14, a set of the capacitors C12 and C15, and a set of the capacitors C13 and C16 can be charged and discharged in a complementary manner by repeating a first phase and a second phase.

Specifically, in the first phase, the switches S12, S13, S22, S23, S32, S33, S42, and S43 are ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

Meanwhile, in the second phase, the switches S11, S14, S21, S24, S31, S34, S41, and S44 are ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

By repeating the first phase and the second phase, for example, one of the capacitors C12 and C15 can be discharged to the capacitor C30 while the other of the capacitors C12 and C15 is being charged from the node N2. That is, the capacitors C12 and C15 are configured to be charged and discharged in a complementary manner.

Like the set of the capacitors C12 and C15, each of the set of the capacitors C11 and C14 and the set of the capacitors C13 and C16 can also be charged and discharged in a complementary manner by repeating the first phase and the second phase.

Each of the capacitors C10, C20, C30, and C40 functions as a smoothing capacitor. That is, each of the capacitors C10, C20, C30, and C40 is used for holding and smoothing the voltages V1 to V4 in the nodes N1 to N4.

The capacitor C10 is connected between the node N1 and the ground. Specifically, one of two electrodes of the capacitor C10 is connected to the node N1.

Meanwhile, the other of the two electrodes of the capacitor C10 is connected to the ground.

The capacitor C20 is connected between the nodes N2 and N1. Specifically, one of two electrodes of the capacitor C20 is connected to the node N2. Meanwhile, the other of the two electrodes of the capacitor C20 is connected to the node N1.

The capacitor C30 is connected between the nodes N3 and N2. Specifically, one of two electrodes of the capacitor C30 is connected to the node N3. Meanwhile, the other of the two electrodes of the capacitor C30 is connected to the node N2.

The capacitor C40 is connected between the nodes N4 and N3. Specifically, one of two electrodes of the capacitor C40 is connected to the node N4. Meanwhile, the other of the two electrodes of the capacitor C40 is connected to the node N3.

The switch S11 is connected between the one of the two electrodes of the capacitor C11 and the node N3. Specifically, the one end of the switch S11 is connected to the one of the two electrodes of the capacitor C11. Meanwhile, the other end of the switch S11 is connected to the node N3.

The switch S12 is connected between the one of the two electrodes of the capacitor C11 and the node N4. Specifically, the one end of the switch S12 is connected to the one of the two electrodes of the capacitor C11. Meanwhile, the other end of the switch S12 is connected to the node N4.

The switch S21 is an example of a first switch and is connected between the one of the two electrodes of the capacitor C12 and the node N2. Specifically, the one end of the switch S21 is connected to the one of the two electrodes of the capacitor C12 and the other of the two electrodes of the capacitor C11. Meanwhile, the other end of the switch S21 is connected to the node N2.

The switch S22 is an example of a third switch and is connected between the one of the two electrodes of the capacitor C12 and the node N3. Specifically, the one end of the switch S22 is connected to the one of the two electrodes of the capacitor C12 and the other of the two electrodes of the capacitor C11. Meanwhile, the other end of the switch S22 is connected to the node N3.

The switch S31 is an example of a fourth switch and is connected between the other of the two electrodes of the capacitor C12 and the node N1. Specifically, the one end of the switch S31 is connected to the other of the two electrodes of the capacitor C12 and the one of the two electrodes of the capacitor C13. Meanwhile, the other end of the switch S31 is connected to the node N1.

The switch S32 is an example of a second switch and is connected between the other of the two electrodes of the capacitor C12 and the node N2. Specifically, the one end of the switch S32 is connected to the other of the two electrodes of the capacitor C12 and the one of the two electrodes of the capacitor C13. Meanwhile, the other end of the switch S32 is connected to the node N2. That is, the other end of the switch S32 is connected to the other end of the switch S21.

The switch S41 is connected between the other of the two electrodes of the capacitor C13 and the ground. Specifically, the one end of the switch S41 is connected to the other of the two electrodes of the capacitor C13. Meanwhile, the other end of the switch S41 is connected to the ground.

The switch S42 is connected between the other of the two electrodes of the capacitor C13 and the node N1. Specifically, the one end of the switch S42 is connected to the other of the two electrodes of the capacitor C13. Meanwhile, the other end of the switch S42 is connected to the node N1. That is, the other end of the switch S42 is connected to the other end of the switch S31.

The switch S13 is connected between the one of the two electrodes of the capacitor C14 and the node N3. Specifically, the one end of the switch S13 is connected to the one of the two electrodes of the capacitor C14. Meanwhile, the other end of the switch S13 is connected to the node N3. That is, the other end of the switch S13 is connected to the other end of the switch S11 and the other end of the switch S22.

The switch S14 is connected between the one of the two electrodes of the capacitor C14 and the node N4. Specifically, the one end of the switch S14 is connected to the one of the two electrodes of the capacitor C14. Meanwhile, the other end of the switch S14 is connected to the node N4. That is, the other end of the switch S14 is connected to the other end of the switch S12.

The switch S23 is an example of a fifth switch and is connected between the one of the two electrodes of the capacitor C15 and the node N2. Specifically, the one end of the switch S23 is connected to the one of the two electrodes of the capacitor C15 and the other of the two electrodes of the capacitor C14. Meanwhile, the other end of the switch S23 is connected to the node N2. That is, the other end of the switch S23 is connected to the other end of the switch S21 and the other end of the switch S32.

The switch S24 is an example of a seventh switch and is connected between the one of the two electrodes of the capacitor C15 and the node N3. Specifically, the one end of the switch S24 is connected to the one of the two electrodes of the capacitor C15 and the other of the two electrodes of the capacitor C14. Meanwhile, the other end of the switch S24 is connected to the node N3. That is, the other end of the switch S24 is connected to the other end of the switch S11, the other end of the switch S22, and the other end of the switch S13.

The switch S33 is an example of an eighth switch and is connected between the other of the two electrodes of the capacitor C15 and the node N1. Specifically, the one end of the switch S33 is connected to the other of the two electrodes of the capacitor C15 and the one of the two electrodes of the capacitor C16. Meanwhile, the other end of the switch S33 is connected to the node N1. That is, the other end of the switch S33 is connected to the other end of the switch S31 and the other end of the switch S42.

The switch S34 is an example of a sixth switch and is connected between the other of the two electrodes of the capacitor C15 and the node N2. Specifically, the one end of the switch S34 is connected to the other of the two electrodes of the capacitor C15 and the one of the two electrodes of the capacitor C16. Meanwhile, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. Specifically, the one end of the switch S43 is connected to the other of the two electrodes of the capacitor C16. Meanwhile, the other end of the switch S43 is connected to the ground.

The switch S44 is connected between the other of the two electrodes of the capacitor C16 and the node N1. Specifically, the one end of the switch S44 is connected to the other of the two electrodes of the capacitor C16. Meanwhile, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43 and a second set of switches including the switches S11, S14, S21, S24, S31, S34, S41, and S44 are switched ON and OFF in a complementary manner. Specifically, in the first phase, the first set of switches is ON, and the second set of switches is OFF. Conversely, in the second phase, the first set of switches is OFF, and the second set of switches is ON.

For example, charging of the capacitors C10 to C40 from the capacitors C11 to C13 is executed in one of the first phase and the second phase, and charging of the capacitors C10 to C40 from the capacitors C14 to C16 is executed in the other of the first phase and the second phase. That is, the capacitors C10 to C40 are always charged from the capacitors C11 to C13 or from the capacitors C14 to C16. Thus, even in a case where a current flows at a high speed from the nodes N1 to N4 to the supply modulators 30A and 30B, a change in potentials of the nodes N1 to N4 is suppressed because the nodes N1 to N4 are supplemented with charges at a high speed.

The switched-capacitor circuit 20, by operating in the above manner, can maintain almost equal voltages at both ends of each of the capacitors C10, C20, C30, and C40. Specifically, the voltages V1 to V4 (voltages with respect to the ground potential) satisfying V1:V2:V3:V4=1:2:3:4 are maintained in four nodes labeled V1 to V4. Voltage levels of the voltages V1 to V4 correspond to the plurality of discrete voltage levels that can be supplied to the supply modulators 30A and 30B by the switched-capacitor circuit 20.

It should be appreciated that the voltage ratio V1:V2:V3:V4 is not limited to 1:2:3:4. For example, the voltage ratio V1:V2:V3:V4 may be 1:2:4:8 in an alternative aspect.

In addition, the configuration of the switched-capacitor circuit 20 illustrated in FIG. 2 is an example, and the present disclosure is not limited thereto. While the switched-capacitor circuit 20 is configured to supply voltages of four discrete voltage levels in FIG. 2, the exemplary aspect of present disclosure is not limited thereto. The switched-capacitor circuit 20 maybe configured to supply voltages of any number of discrete voltage levels of two or more. For example, in the case of supplying voltages of two discrete voltage levels, the switched-capacitor circuit 20 may include at least the capacitors C12 and C15 and the switches S21 to S24 and S31 to S34.

### [1.2.2 Circuit Configurations of Supply Modulators 30A and 30B]

Next, the circuit configurations of the supply modulators 30A and 30B will be described.

As illustrated in FIG. 2, the supply modulator 30A includes input terminals 131A to 134A, switches S51A to S54A, an output terminal 130A, and control terminals 135A and 136A. In addition, the supply modulator 30B includes input terminals 131B to 134B, switches S51B to S54B, an output terminal 130B, and control terminals 135B and 136B. Hereinafter, the supply modulator 30A will be described, and description of the supply modulator 30B will be omitted because description of the supply modulator 30B is approximately the same as description of the supply modulator 30A in which reference numeral “A” is replaced with “B”. The supply modulator 30B may be integrated into the supply modulator 30A.

The output terminal 130A is connected to the filter circuit 40A. The output terminal 130A is a terminal for supplying a voltage selected from the voltages V1 to V4 to the filter circuit 40A.

The input terminals 131A to 134A are connected to the nodes N4 to N1 of the switched-capacitor circuit 20, respectively. The input terminals 131A to 134A are terminals for receiving the voltages V4 to V1 from the switched-capacitor circuit 20.

The control terminals 135A and 136A are input terminals of the digital control signal. That is, the control terminals 135A and 136A are terminals for receiving the digital control signal indicating one of the voltages V1 to V4. The supply modulator 30A controls the switches S51A to S54A to be ON/OFF such that a voltage level indicated by the digital control signal is selected.

According to an exemplary aspect, two digital control logic/line (DCL) signals can be used as the digital control signal received through the control terminals 135A and 136A. Each of the two DCL signals is a 1-bit signal. Each of the voltages V1 to V4 is indicated by a combination of two 1-bit signals. For example, V1, V2, V3, and V4 are indicated by “00”, “01”, “10”, and “11”, respectively. A gray code may be used for representing the voltage level in an exemplary aspect.

It is also noted that while two DCL signals are used in the present embodiment, it should be appreciated that any number of DCL signals of one or three or more may be used in accordance with the number of voltage levels. In addition, the digital control signal is not limited to the DCL signal and may be the control signal of the source-synchronous scheme.

The switch S51A is connected between the input terminal 131A and the output terminal 130A. Specifically, the switch S51A includes a terminal connected to the input terminal 131A and a terminal connected to the output terminal 130A. In this connection configuration, the switch S51A can be switched ON/OFF to switch between a connected state and a non-connected state between the input terminal 131A and the output terminal 130A.

The switch S52A is an example of a tenth switch and is connected between the input terminal 132A and the output terminal 130A. Specifically, the switch S52A includes a terminal connected to the input terminal 132A and a terminal connected to the output terminal 130A. In this connection configuration, the switch S52A can be switched ON/OFF to switch between a connected state and a non-connected state between the input terminal 132A and the output terminal 130A.

The switch S53A is an example of a ninth switch and is connected between the input terminal 133A and the output terminal 130A. Specifically, the switch S53A includes a terminal connected to the input terminal 133A and a terminal connected to the output terminal 130A. In this connection configuration, the switch S53A can be switched ON/OFF to switch between a connected state and a non-connected state between the input terminal 133A and the output terminal 130A.

The switch S54A is connected between the input terminal 134A and the output terminal 130A. Specifically, the switch S54A includes a terminal connected to the input terminal 134A and a terminal connected to the output terminal 130A. In this connection configuration, the switch S54A can be switched ON/OFF to switch between a connected state and a non-connected state between the input terminal 134A and the output terminal 130A.

The switches S51A to S54A are controlled to be exclusively ON. That is, only one of the switches S51A to S54A is ON, and the rest of the switches S51A to S54A are OFF. Accordingly, the supply modulator 30A can output one voltage selected from the voltages V1 to V4.

The configuration of the supply modulator 30A illustrated in FIG. 2 is an example, and the exemplary aspects of the present disclosure are not limited thereto. Particularly, the supply modulator 30A may have any configuration as long as the switches S51A to S54A are configured to selectively connect at least one of the four input terminals 131A to 134A to the output terminal 130A. For example, the supply modulator 30A may further include a switch connected between the switches S51A to S53A, and the switch S54A and the output terminal 130A. In addition, for example, the supply modulator 30A may further include a switch connected between the switches S51A and S52A, and the switches S53A and S54A and the output terminal 130A.

When voltages of two discrete voltage levels are supplied from the switched-capacitor circuit 20, the supply modulator 30A may include at least the switches S52A and S53A.

### [1.2.3 Circuit Configuration of Pre-Regulator Circuit 10]

First, a configuration of the pre-regulator circuit 10 will be described. As illustrated in FIG. 2, the pre-regulator circuit 10 includes an input terminal 110, output terminals 111 to 114, a control terminal 117, switches S61 to S63, S71, and S72, a power inductor L71, and capacitors C61 to C64.

The input terminal 110 is an input terminal of a direct current voltage. That is, the input terminal 110 is a terminal for receiving the input voltage from the direct current power source 50.

The output terminal 111 is an output terminal of the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal of the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal of the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal of the voltage V1. That is, the output terminal 114 is a terminal for supplying the voltage V1 to the switched-capacitor circuit 20. The output terminal 114 is connected to the node N1 of the switched-capacitor circuit 20.

The control terminal 117 is an input terminal of the digital control signal. That is, the control terminal 117 is a terminal for receiving the digital control signal for controlling the pre-regulator circuit 10. For example, a control signal of the source-synchronous scheme for transmitting a data signal and a clock signal can be used as the digital control signal received through the control terminal 117. However, it an alternative aspect, a control signal of the clock-embedded scheme in which a clock is embedded in a data signal may be used as the digital control signal. Moreover, the control terminal 117 may be integrated with the control terminal 120.

The switch S71 is an example of an eleventh switch and is connected between the input terminal 110 and one end of the power inductor L71. Specifically, the switch S71 includes a terminal connected to the input terminal 110 and a terminal connected to the one end of the power inductor L71. In this connection configuration, the switch S71 can be switched ON/OFF to switch between a connected state and a non-connected state between the input terminal 110 and the one end of the power inductor L71.

The switch S72 is an example of a twelfth switch and is connected between the one end of the power inductor L71 and the ground. Specifically, the switch S72 includes a terminal connected to the one end of the power inductor L71 and a terminal connected to the ground. In this connection configuration, the switch S72 can be switched ON/OFF to switch between a connected state and a non-connected state between the one end of the power inductor L71 and the ground.

The switch S61 is connected between the other end of the power inductor L71 and the output terminal 111. Specifically, the switch S61 includes a terminal connected to the other end of the power inductor L71 and a terminal connected to the output terminal 111. In this connection configuration, the switch S61 can be switched ON/OFF to switch between a connected state and a non-connected state between the other end of the power inductor L71 and the output terminal 111.

The switch S62 is connected between the other end of the power inductor L71 and the output terminal 112. Specifically, the switch S62 includes a terminal connected to the other end of the power inductor L71 and a terminal connected to the output terminal 112. In this connection configuration, the switch S62 can be switched ON/OFF to switch between a connected state and a non-connected state between the other end of the power inductor L71 and the output terminal 112.

The switch S63 is connected between the other end of the power inductor L71 and the output terminal 113. Specifically, the switch S63 includes a terminal connected to the other end of the power inductor L71 and a terminal connected to the output terminal 113. In this connection configuration, the switch S63 can be switched ON/OFF to switch between a connected state and a non-connected state between the other end of the power inductor L71 and the output terminal 113.

One of two electrodes of the capacitor C61 is connected to the switch S61 and the output terminal 111. The other of the two electrodes of the capacitor C61 is connected to the switch S62, the output terminal 112, and one of two electrodes of the capacitor C62.

The one of the two electrodes of the capacitor C62 is connected to the switch S62, the output terminal 112, and the other of the two electrodes of the capacitor C61.

The other of the two electrodes of the capacitor C62 is connected to a path connecting the switch S63, the output terminal 113, and one of two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of two electrodes of the capacitor C64.

The one of the two electrodes of the capacitor C64 is connected to the output terminal 114 and the other of the two electrodes of the capacitor C63. The other of the two electrodes of the capacitor C64 is connected to the ground.

The switches S61 to S63 are controlled to be exclusively ON. That is, only one of the switches S61 to S63 is ON, and the rest of the switches S61 to S63 are OFF. By causing only one of the switches S61 to S63 to be ON, the pre-regulator circuit 10 can change the voltage to be supplied to the switched-capacitor circuit 20 among the voltage levels of the voltages V2 to V4.

The pre-regulator circuit 10 configured in the above manner can supply charges to the switched-capacitor circuit 20 through at least one of the output terminals 111 to 113.

In a case where the input voltage is converted into one first voltage, the pre-regulator circuit 10 may include at least the switches S71 and S72 and the power inductor L71.

### [1.2.4 Circuit Configurations of Filter Circuits 40A and 40B]

Next, the circuit configurations of the filter circuits 40A and 40B will be described. The filter circuits 40A and 40B include a low pass filter (LPF). Specifically, as illustrated in FIG. 2, the filter circuit 40A includes inductors L51A to L53A, capacitors C51A and C52A, a resistor R51A, an input terminal 140A, and an output terminal 141A. In addition, the filter circuit 40B also includes an LPF and includes inductors L51B to L53B, capacitors C51B and C52B, a resistor R51B, an input terminal 140B, and an output terminal 141B. Hereinafter, the filter circuit 40A will be described, and description of the filter circuit 40B will be omitted because description of the filter circuit 40B is approximately the same as description of the filter circuit 40A in which reference numeral “A” is replaced with “B”.

The input terminal 140A is an input terminal of the voltage selected by the supply modulator 30A. That is, the input terminal 140A is a terminal for receiving the voltage selected from the plurality of voltages V1 to V4.

The output terminal 141A is an output terminal of the power supply voltage V_{ETA}. That is, the output terminal 141A is a terminal for supplying the power supply voltage V_{ETA} to the power amplifier 2A.

According to an exemplary aspect, the inductors L51A to L53A, the capacitors C51A and C52A, and the resistor R51A are configured to form a low pass filter.

Accordingly, the filter circuit 40A can reduce a radio frequency component included in the power supply voltage. For example, in a case where a predetermined band is a frequency band for frequency division duplex (FDD), the filter circuit 40A is configured to reduce a frequency component of a gap between an uplink operation band and a downlink operation band of the predetermined band.

It is noted that the configuration of the filter circuit 40A illustrated in FIG. 2 is an example, and the exemplary aspects are not limited thereto. For example, the filter circuit 40A may include neither the inductor L53A nor the resistor R51A. In addition, for example, the filter circuit 40A may include an inductor connected to one of two electrodes of the capacitor C51A or may include an inductor connected to one of two electrodes of the capacitor C52A.

### [2 Description of Digital ET Mode]

Here, the digital ET mode will be described in comparison with an ET mode in the related art (hereinafter, referred to as an analog ET mode) with reference to FIGS. 3A and 3B. FIG. 3A is a graph illustrating an example of a trend of the power supply voltage in the digital ET mode. FIG. 3B is a graph illustrating an example of a trend of the power supply voltage in the analog ET mode. In FIGS. 3A and 3B, a horizontal axis represents time, and a vertical axis represents a voltage. In addition, a thick solid line represents the power supply voltage, and a thin solid line (e.g., a waveform) represents the modulated signal.

In the digital ET mode, as illustrated in FIG. 3A, an envelope of the modulated signal is tracked by changing the power supply voltage to the plurality of discrete voltage levels in one frame. Consequently, the power supply voltage signal forms a rectangular wave. In the digital ET mode, the power supply voltage level is selected or set, from the plurality of discrete voltage levels, based on the envelope signal.

For purposes of this disclosure, a frame is a unit forming the radio frequency signal (e.g., modulated signal). For example, in 5G NR or LTE, a frame includes 10 subframes, each subframe includes a plurality of slots, and each slot includes a plurality of symbols. A subframe length is 1 ms, and a frame length is 10 ms.

In the analog ET mode, as illustrated in FIG. 3B, the envelope of the modulated signal is tracked by continuously changing the power supply voltage. In the analog ET mode, the power supply voltage is determined based on the envelope signal. In the analog ET mode, it is difficult for the power supply voltage to track the envelope in a case where the envelope of the modulated signal changes at a high speed.

### Example 1

### [3.1 Component Disposition of Tracker Module 100]

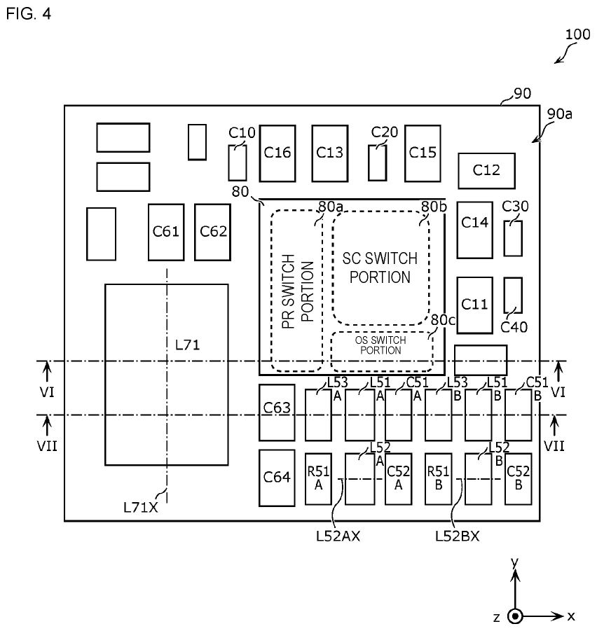

Next, a tracker module 100 on which the pre-regulator circuit 10, the switched-capacitor circuit 20, the supply modulators 30A and 30B, and the filter circuits 40A and 40B are mounted will be described with reference to FIGS. 4 to 7 as a first exemplary aspect (Example 1) of the power supply circuit 1 configured in the above manner.

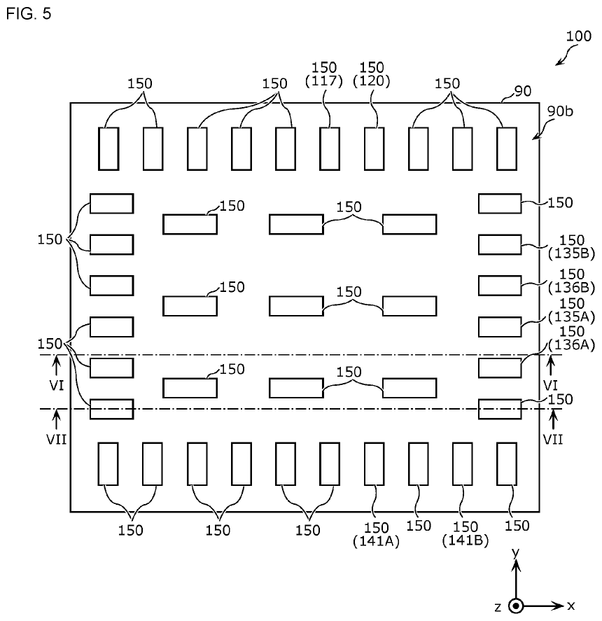

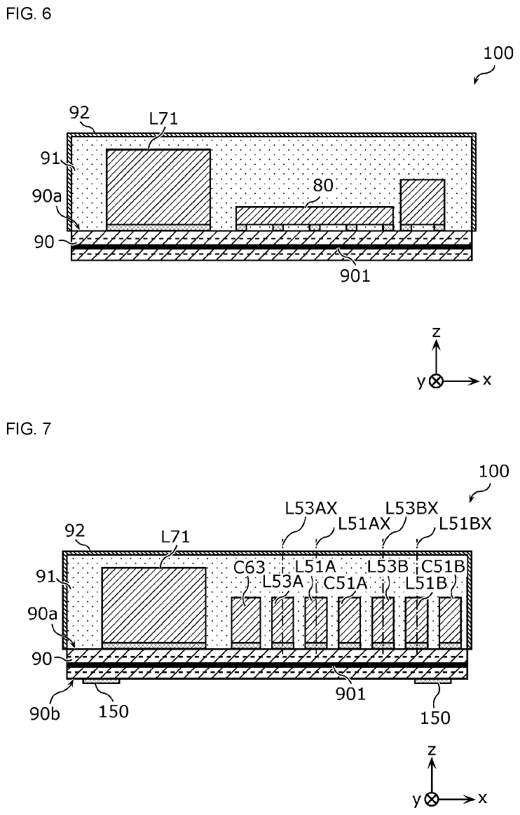

FIG. 4 is a plan view of the tracker module 100 according to the current exemplary aspect. FIG. 5 is a plan view of the tracker module 100 according to the exemplary aspect and is a see-through diagram of a main surface 90b side of a module laminate 90 from the positive side of the z axis. FIGS. 6 and 7 are sectional views of the tracker module 100 according to the current exemplary aspect. Sections of the tracker module 100 in FIGS. 6 and 7 are sections taken along a line VI-VI and a line VII-VII in FIGS. 4 and 5, respectively.

In FIGS. 4 to 6, a part of wires connecting a plurality of circuit components disposed on the module laminate 90 is not illustrated. In FIGS. 4 and 5, a resin member 91 covering the plurality of circuit components and a shield electrode layer 92 covering a surface of the resin member 91 are not illustrated. In FIGS. 4 and 6, a block without a reference numeral indicates any circuit component that may be omitted in an alternative exemplary aspect.

The tracker module 100 includes the module laminate 90, the resin member 91, and a plurality of land electrodes 150, in addition to the plurality of circuit components including the active elements and the passive elements included in the pre-regulator circuit 10, the switched-capacitor circuit 20, the supply modulators 30A and 30B, and the filter circuits 40A and 40B illustrated in FIG. 2.

The module laminate 90 has main surfaces 90a and 90b that face each other. The main surfaces 90a and 90b are examples of a first main surface and a second main surface, respectively. In the module laminate 90, a wire layer, a via conductor, a ground plane 901, and the like are formed. While the module laminate 90 has a rectangular shape in a plan view in FIGS. 4 and 5, the exemplary aspect is not limited to the shape.

It is noted that the module laminate 90 maybe referred to as a “module substrate” and can be one of a low temperature co-fired ceramics (LTCC) laminate, a high temperature co-fired ceramics (HTCC) laminate, a component-embedded board, a laminate having a redistribution layer (RDL), or a printed circuit board having a laminated structure of a plurality of dielectric layers.

An integrated circuit 80, the capacitors C10 to C16, C20, C30, C40, C51A, C51B, C52A, C52B, and C61 to C64, the inductors L51A to L53A and L51B to L53B, the resistors R51A and R51B, and the resin member 91 are disposed on the main surface 90a.

The integrated circuit 80 includes a PR switch portion 80a, an SC switch portion 80b, and an OS switch portion 80c. The PR switch portion 80a includes the switches S61 to S63, S71, and S72. The PR switch portion 80a is an example of a first switch portion and includes the switches S61 to S63, S71, and S72. The SC switch portion 80b is an example of a second switch portion and includes the switches S11 to S14,

S21 to S24, S31 to S34, and S41 to S44. The OS switch portion 80c is an example of a third switch portion and includes the switches S51A to S54A and S51B to S54B.

While the PR switch portion 80a, the SC switch portion 80b, and the OS switch portion 80c are included in the single integrated circuit 80 in FIG. 4, the exemplary aspects of the present disclosure are not limited thereto. For example, the PR switch portion 80a and the SC switch portion 80b may be included in one integrated circuit, and the OS switch portion 80c may be included in another integrated circuit. In addition, for example, the SC switch portion 80b and the OS switch portion 80c may be included in one integrated circuit, and the PR switch portion 80a may be included in another integrated circuit. In addition, the PR switch portion 80a and the OS switch portion 80c may be included in one integrated circuit, and the SC switch portion 80b may be included in another integrated circuit. In addition, for example, the PR switch portion 80a, the SC switch portion 80b, and the OS switch portion 80c may be individually included in three integrated circuits.

In addition, while the integrated circuit 80 has a rectangular shape in a plan view of the module laminate 90 in FIG. 4, the exemplary aspect is not limited to the shape.

In an exemplary aspect, the integrated circuit 80 is configured using, for example, a complementary metal oxide semiconductor (CMOS) and specifically, may be manufactured through a silicon on insulator (SOI) process. However, it is noted that the integrated circuit 80 is not limited to the CMOS.

In an exemplary aspect, each of the capacitors C10 to C16, C20, C30, C40, C51A, C52A, C51B, C52B, and C61 to C64 is mounted as a chip capacitor. Accordingly, the chip capacitor can be a surface mount device (SMD) forming a capacitor. However, it is noted that mounting of the plurality of capacitors is not limited to the chip capacitor. For example, a part or all of the plurality of capacitors may be included in an integrated passive device (IPD) or may be included in the integrated circuit 80.

In an exemplary aspect, each of the power inductor L71 and the inductors L51A to L53A and L51B to L53B is mounted as a chip inductor. Accordingly, the chip inductor can be an SMD forming an inductor. However, it is noted that mounting of the plurality of inductors is not limited to the chip inductor. For example, the plurality of inductors may be included in an IPD.

In an exemplary aspect, each of the resistors R51A and R51B is mounted as a chip resistor. Accordingly, the chip resistor can be an SMD forming a resistor. However, it is noted that mounting of the resistors R51A and R51B is not limited to the chip resistor. For example, the resistors R51A and R51B may be included in an IPD.

Accordingly, the plurality of capacitors, the plurality of inductors, and the plurality of resistors disposed on the main surface 90a are disposed in groups for each circuit around the integrated circuit 80.

Specifically, in a plan view of the module laminate 90, a group of the power inductor L71 and the capacitors C61 to C64 included in the pre-regulator circuit 10 is disposed in a region interposed between a straight line along a left edge of the integrated circuit 80 and a straight line along a left edge of the module laminate 90 on the main surface 90a, except the capacitors C63 and C64. Accordingly, the group of the circuit components included in the pre-regulator circuit 10 is disposed close to the PR switch portion 80a in the integrated circuit 80.

In the exemplary aspect, the power inductor L71 is disposed adjacent to the integrated circuit 80. More specifically, the power inductor L71 is disposed adjacent to the PR switch portion 80a in the integrated circuit 80. Accordingly, the PR switch portion 80a is disposed closer to the power inductor L71 than each of the SC switch portion 80b and the OS switch portion 80c is. In addition, as illustrated in FIG. 4, the power inductor L71 is disposed such that a winding axis L71X of the power inductor L71 is parallel to the y axis.

For purposes of this disclosure, a “winding axis of an inductor” refers to an imaginary axis as a center axis of a coil forming the inductor. Accordingly, the winding axis of the inductor can be specified from the center axis of winding of the coil. Alternatively, the winding axis of the inductor can also be estimated from a magnetic axis of the coil.

The capacitor C63 is disposed between the power inductor L71 and each of the inductors L51A, L53A, L51B, and L53B in a plan view of the module laminate 90. Furthermore, the capacitor C64 is disposed between the power inductor L71 and each of the inductors L52A and L52B. Circuit components disposed between the power inductor L71 and the inductors included in the filter circuits 40A and 40B are not limited to the capacitors C63 and C64.

In a plan view of the module laminate 90, a group of the capacitors C10 to C16, C20, C30, and C40 included in the switched-capacitor circuit 20 is disposed in a region interposed between a straight line along an upper edge of the integrated circuit 80 and a straight line along an upper edge of the module laminate 90 on the main surface 90a and in a region interposed between the straight line along a right edge of the integrated circuit 80 and a straight line along a right edge of the module laminate 90 on the main surface 90a. Accordingly, the group of the circuit components included in the switched-capacitor circuit 20 is disposed close to the SC switch portion 80b in the integrated circuit 80. That is, the SC switch portion 80b is disposed closer to the switched-capacitor circuit 20 than each of the PR switch portion 80a and the OS switch portion 80c is.

In a plan view of the module laminate 90, a group of the capacitors C51A, C51B, C52A, and C52B, the inductors L51A to L53A and L51B to L53B, and the resistors R51A and R51B included in the filter circuits 40A and 40B is disposed in a region interposed between a straight line along a lower edge of the integrated circuit 80 and a straight line along a lower edge of the module laminate 90 on the main surface 90a. Accordingly, the group of the circuit components included in the filter circuits 40A and 40B is disposed close to the OS switch portion 80c in the integrated circuit 80. That is, the OS switch portion 80c is disposed closer to the filter circuits 40A and 40B than each of the PR switch portion 80a and the SC switch portion 80b is.

As illustrated in FIG. 4, the inductors L52A and L52B are disposed such that winding axes L52AX and L52BX of the inductors L52A and L52B are parallel to the x axis. As illustrated in FIG. 7, the inductors L51A, L51B, L53A, and L53B are disposed such that winding axes L51AX, L51BX, L53AX, and L53BX of the inductors L51A, L51B, L53A, and L53B are parallel to the z axis. That is, the winding axis L71X of the power inductor L71 is perpendicular to each of the winding axes L51AX to L53AX and L51BX to L53BX of the inductors L51A to L53A and L51B to L53B.

In an exemplary aspect, the winding axis L71X may not be perpendicular to each of the winding axes L51AX to L53AX and L51BX to L53BX. The winding axis L71X may be perpendicular to at least one of the winding axes L51AX to L53AX and L51BX to L53BX. In addition, directions of the winding axes L51AX to L53AX, L51BX to L53BX, and L71X in FIG. 7 are examples, and the exemplary aspects of the present disclosure are not limited thereto. For example, the winding axis L71X may be parallel to the x axis or the z axis, or the winding axis L71X may not be parallel to any of the x axis, y axis, and z axis.

At least a part of the filter circuit 40A and at least a part of the filter circuit 40B are disposed adjacent to the same edge (in FIG. 4, the lower edge) among the four edges of the integrated circuit 80. Specifically, at least one of the circuit components included in the filter circuit 40A (in FIG. 4, the capacitor C51A and the inductors L51A and L53A) is disposed adjacent to the lower edge of the integrated circuit 80. Furthermore, at least one of the circuit components included in the filter circuit 40B (in FIG. 4, the inductor L53B) is disposed adjacent to the lower edge of the integrated circuit 80.

The plurality of land electrodes 150 are disposed on the main surface 90b. The plurality of land electrodes 150 function as a plurality of external connection terminals including a ground terminal in addition to the input terminal 110, the output terminals 141A and 141B, and the control terminals 117, 120, 135A, 135B, 136A, and 136B illustrated in FIG. 2. The plurality of land electrodes 150 are electrically connected to a plurality of electronic components disposed on the main surface 90a through the via conductor and the like formed in the module laminate 90. While copper electrodes can be used as the plurality of land electrodes 150, solder electrodes or the like may be used as the plurality of land electrodes. In addition, a plurality of bump electrodes or a plurality of post electrodes may be used as the plurality of external connection terminals instead of the plurality of land electrodes 150.

The resin member 91 covers at least a part of the main surface 90a and at least a part of the plurality of electronic components on the main surface 90a. The resin member 91 has a function of securing reliability such as mechanical strength and humidity resistance of the plurality of electronic components on the main surface 90a. In an alternative aspect, the resin member 91 is not included in the tracker module 100.

The shield electrode layer 92 is an example of a metal layer and is a thin metal film formed using, for example, sputtering. The shield electrode layer 92 is formed to cover a surface (e.g., an upper surface and side surfaces) of the resin member 91. The shield electrode layer 92 is connected to the ground and suppresses permeation of external noise into the electronic components configuring the tracker module 100 and interference of noise generated in the tracker module 100 with other modules or other devices. In an alternative aspect, the shield electrode layer 92 is not included in the tracker module 100.

It is noted that the configuration of the tracker module 100 is an example, and the present disclosure is not limited thereto. For example, a part of the capacitors and the inductors disposed on the main surface 90a may be formed in the module laminate 90. In addition, a part of the capacitors and the inductors disposed on the main surface 90a may not be included in the tracker module and/or not disposed on the module laminate 90 in an alternative aspect.

### [3.2 Effect and Like]

As described above, the tracker module 100 according to the current exemplary aspect includes the module laminate 90, the integrated circuit 80 disposed on the module laminate 90, and the power inductor L71 disposed on the module laminate 90. The integrated circuit 80 includes at least one switch included in the pre-regulator circuit 10 configured to convert the input voltage into the first voltage using the power inductor L71, at least one switch included in the switched-capacitor circuit 20 configured to generate the plurality of discrete voltages from the first voltage, and at least one switch included in the supply modulator 30A configured to selectively output, based on the envelope signal, at least one of the plurality of discrete voltages.

In addition, from another point of view, the tracker module 100 according to the current exemplary aspect includes the module laminate 90, the integrated circuit 80 disposed on the module laminate 90, and the power inductor L71 disposed on the module laminate 90. The integrated circuit 80 includes at least one switch included in the pre-regulator circuit 10 configured to convert the input voltage into the first voltage using the power inductor L71, at least one switch included in the switched-capacitor circuit 20 configured to generate the plurality of discrete voltages from the first voltage, and at least one switch included in the supply modulator 30A that includes the control terminal 135A and/or 136A connected to the RFIC 5 and that is configured to selectively output at least one of the plurality of discrete voltages.

In addition, from another point of view, the tracker module 100 according to the current exemplary aspect includes the module laminate 90, the integrated circuit 80 disposed on the module laminate 90, and the power inductor L71 disposed on the module laminate 90. The integrated circuit 80 includes at least one switch included in the pre-regulator circuit 10, at least one switch included in the switched-capacitor circuit 20, and at least one switch included in the supply modulator 30A. The switched-capacitor circuit 20 includes the capacitor C12 including the first electrode and the second electrode and the capacitor C15 including the third electrode and the fourth electrode. The at least one switch included in the switched-capacitor circuit 20 includes the switches S21 to S24 and S31 to S34. A first end of the switch S21 and a first end of the switch S22 are connected to the first electrode. The first end of the switch S32 and the first end of the switch S31 are connected to the second electrode. The first end of the switch S23 and the first end of the switch S24 are connected to the third electrode. The first end of the switch S34 and the first end of the switch S33 are connected to the fourth electrode. The second end of the switch S21, the second end of the switch S32, the second end of the switch S23, and the second end of the switch S34 are connected to each other. The second end of the switch S22 is connected to the second end of the switch S24. The second end of the switch S31 is connected to the second end of the switch S33. The supply modulator 30A includes the output terminal 130A. The at least one switch included in the supply modulator 30A includes the switch S53A connected between the output terminal 130A and the second end of the switch S21, the second end of the switch S32, the second end of the switch S23, and the second end of the switch S34, and the switch S52A connected between the output terminal 130A and the second end of the switch S22 and the second end of the switch S24. The pre-regulator circuit 10 includes the power inductor L71 and the input terminal 110. The at least one switch included in the pre-regulator circuit 10 includes the switch S71 connected between the input terminal 110 and the first end of the power inductor L71, and the switch S72 connected between the first end of the power inductor L71 and the ground. The second end of the power inductor L71 is connected to the second ends of the switch S21, the switch S32, the switch S23, and the switch S34.

According to this configuration, the power inductor L71 included in the pre-regulator circuit 10 is disposed on the module laminate 90 on which the integrated circuit 80 including at least one switch included in the pre-regulator circuit 10 is disposed. Accordingly, a wire length between the power inductor L71 and the integrated circuit 80 can be shortened compared to a case where the power inductor L71 is disposed on a module laminate separated from the integrated circuit 80. When the wire length between the power inductor L71 and the integrated circuit 80 is shortened, parasitic inductance of the wire can be reduced. Consequently, noise of the first voltage output from the pre-regulator circuit 10 is reduced, and deterioration of characteristics caused by noise is suppressed. Particularly, when the tracker module 100 is used in the digital ET mode, the effect of noise reduction in the pre-regulator circuit 10 is high because noise is superimposed on ringing noise caused by switching among the plurality of discrete second voltages. In addition, in a case where the wire length between the power inductor L71 and the integrated circuit 80 is shortened, a loop area of a path connected to the power inductor L71 through which a high current flows can be reduced. Consequently, generation of a magnetic field caused by a change in the loop area can be suppressed, and EMI with other modules and the like can also be suppressed. Particularly, when the power supply voltages V_{ETA} and V_{ETB} are supplied to the plurality of power amplifiers 2A and 2B through the plurality of supply modulators 30A and 30B in the digital ET mode, the effect of EMI suppression is high because the current flowing through the power inductor L71 is also increased.

In addition, for example, in the tracker module 100 according to the exemplary aspect, the power inductor L71 may be disposed adjacent to the integrated circuit 80.

According to this configuration, the wire length between the power inductor L71 and the integrated circuit 80 is further shortened, and deterioration of characteristics and EMI caused by noise is further suppressed.

In addition, for example, in the tracker module 100 according to the exemplary aspect, the integrated circuit 80 may include the PR switch portion 80a including the at least one switch included in the pre-regulator circuit 10, the SC switch portion 80b including the at least one switch included in the switched-capacitor circuit 20, and the OS switch portion 80c including the at least one switch included in the supply modulator 30A. The PR switch portion 80a may be disposed closer to the power inductor L71 than each of the SC switch portion 80b and the OS switch portion 80c is.

According to this configuration, a wire length between the power inductor L71 and the switch S71 or the like in the integrated circuit 80 is further shortened, and deterioration of characteristics and EMI caused by noise is further suppressed.

In addition, for example, the tracker module 100 according to the exemplary aspect may further include the inductor L51A disposed on the module laminate 90 and a circuit component (for example, the capacitor C63) disposed on the module laminate 90. The supply modulator 30A may be configured to selectively output at least one of the plurality of discrete voltages through the filter circuit 40A including the inductor L51A. The circuit component (for example, the capacitor C63) may be disposed between the power inductor L71 and the inductor L51A in a plan view of the module laminate 90.

According to this configuration, since the circuit component is disposed between the power inductor L71 and the inductor L51A, the power inductor L71 can be disposed to be relatively separated from the inductor L51A. Accordingly, magnetic field coupling (that is, inductive coupling) between the power inductor L71 and the inductor L51A is suppressed, and deterioration of electrical characteristics of the tracker module 100 is also suppressed.

In addition, for example, in the tracker module 100 according to the exemplary aspect, the winding axis L71X of the coil forming the power inductor L71 may be perpendicular to the winding axis L51AX of the coil forming the inductor L51A.

According to this configuration, a magnetic axis of the power inductor L71 can be set to be perpendicular to a magnetic axis of the inductor L51A. Accordingly, magnetic field coupling between the power inductor L71 and the inductor L51A is suppressed, and deterioration of the electrical characteristics of the tracker module 100 is also suppressed.

In addition, for example, the tracker module 100 according to the exemplary aspect may further include the resin member 91 that covers at least a part of the main surface 90a of the module laminate 90 and at least a part of the circuit components on the main surface 90a, and the shield electrode layer 92 that covers at least a part of the surface of the resin member 91.

According to this configuration, radiation of electromagnetic noise generated in the circuit components and the like disposed on the module laminate 90 outside the tracker module 100 is suppressed, and EMI is further suppressed.

### Example 2

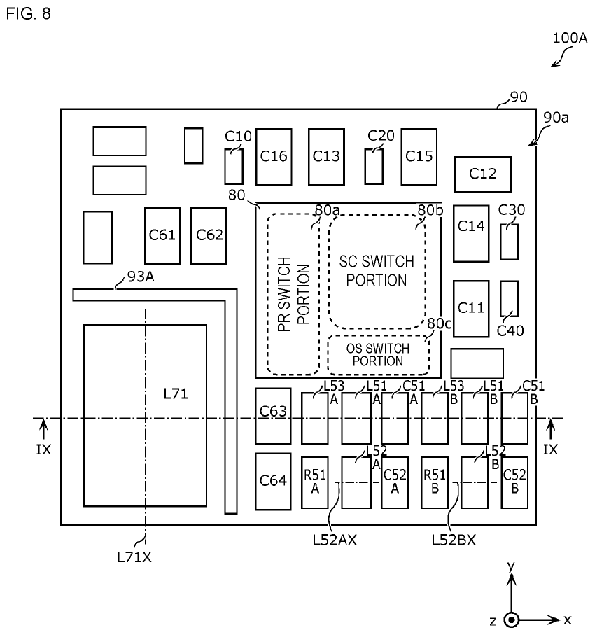

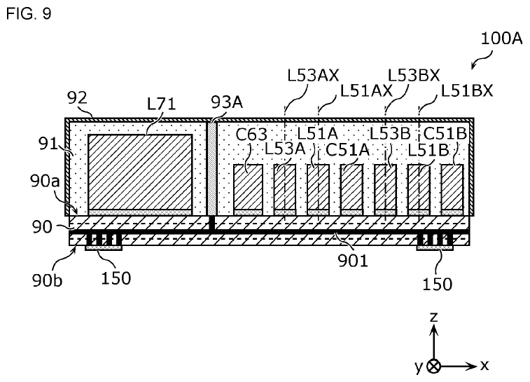

Next, a second exemplary aspect (Example 2) of the power supply circuit 1 will be described. The current exemplary aspect is mainly different from Example 1 in that a metal member 93A is disposed on the main surface 90a of the module laminate 90. Hereinafter, a tracker module 100A according to the current exemplary aspect example will be mainly described with reference to FIGS. 8 and 9, based on its differences from Example 1.

### [4.1 Component Disposition of Tracker Module 100A]

FIG. 8 is a plan view of the tracker module 100A according to the current exemplary aspect. FIG. 9 is a sectional view of the tracker module 100A according to the current exemplary aspect. The section of the tracker module 100A in FIG. 9 is a section taken along a line IX-IX in FIG. 8.

In FIGS. 8 and 9, a part of the wires connecting the plurality of circuit components disposed on the module laminate 90 is omitted. In FIG. 8, the resin member 91 and the shield electrode layer 92 are not illustrated. In addition, in FIG. 8, a block without a reference numeral indicates any circuit component that may be omitted in an alternative aspect.

The tracker module 100A according to the current exemplary aspect further includes the metal member 93A. The metal member 93A is disposed on the main surface 90a of the module laminate 90 and protrudes from the main surface 90a. Thus, at least a part of the metal member 93A is present above the main surface 90a. The metal member 93A is disposed adjacent to the power inductor L71 and is disposed between the power inductor L71 and the filter circuits 40A and 40B in a plan view of the module laminate 90.

The metal member 93A is a ground electrode connected to the ground. The metal member 93A is in contact with the shield electrode layer 92. Specifically, the metal member 93A is in contact with the shield electrode layer 92 on an upper surface of the tracker module 100A. Furthermore, the metal member 93A may be electrically connected to the land electrodes 150 functioning as the ground terminal through a pattern electrode, a via electrode, and the like formed in the module laminate 90.

In FIG. 8, the metal member 93A is a combination of a metal wall that protrudes from the main surface 90a and that extends along the x axis and a metal wall that protrudes from the main surface 90a and that extends along the y axis. A height of each metal wall is higher than a height of the power inductor L71. A shape of the metal member 93A is not limited to the wall. For example, the metal member 93A may be configured with a plurality of bonding wires. In addition, for example, the metal member 93A may be configured with a plurality of metal posts arranged in a row. The shape of the metal member 93A is not limited thereto.

For example, copper, aluminum, or an alloy including copper and/or aluminum can be used as the metal member 93A. A material of the metal member 93A is not limited thereto.

In an alternative aspect, the metal member 93A may not be in contact with the shield electrode layer 92 on the upper surface of the tracker module 100A. In this case, the height of each metal wall may be lower than the height of the power inductor L71. In addition, the metal member 93A may not be connected to ground in an exemplary aspect.

### [4.2 Effect and Like]

As described above, in the tracker module 100A according to the exemplary aspect, the integrated circuit 80 and the power inductor L71 are disposed on the main surface 90a of the module laminate 90. The tracker module 100A further includes the inductor L51A disposed on the main surface 90a of the module laminate 90, and the metal member 93A disposed on the main surface 90a of the module laminate 90. The supply modulator 30A is configured to selectively output at least one of the plurality of discrete voltages through the filter circuit 40A including the inductor L51A. The metal member 93A is disposed between the power inductor L71 and the inductor L51A in a plan view of the module laminate 90.

According to this configuration, since the metal member 93A is disposed between the power inductor L71 and the inductor L51A, magnetic field coupling between the power inductor L71 and the inductor L51A is suppressed.

In addition, for example, in the tracker module 100A according to the exemplary aspect, the metal member 93A can be a ground electrode connected to the ground.

According to this configuration, magnetic field coupling between the power inductor L71 and the inductor L51A is more effectively suppressed.

### Example 3

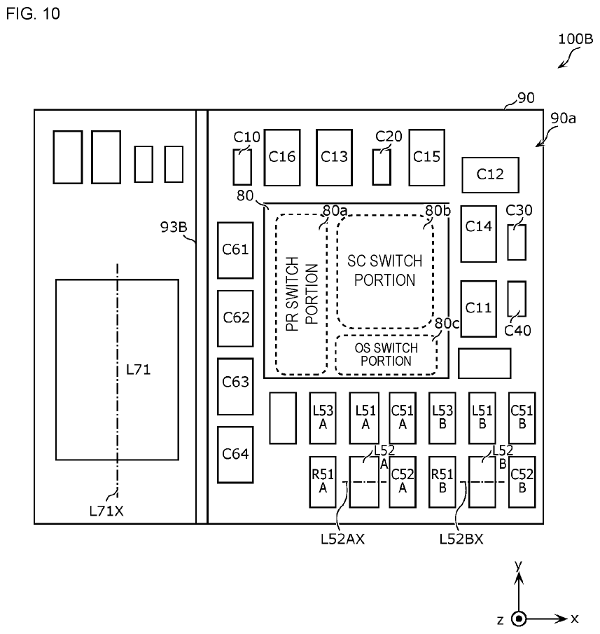

Next, a third exemplary aspect (Example 3) of the power supply circuit 1 will be described. The current exemplary aspect is mainly different from Example 2 in terms of disposition of the power inductor and disposition and the shape of the metal member. Hereinafter, a tracker module 100B according to the current exemplary aspect will be mainly described with reference to FIG. 10, based on its differences from Example 2.

### [5.1 Component Disposition of Tracker Module 100B]

FIG. 10 is a plan view of the tracker module 100B according to the present exemplary aspect. In FIG. 10, the resin member 91 and the shield electrode layer 92 are not illustrated. In addition, in FIG. 10, a block without a reference numeral indicates any circuit component that may be omitted in an alternative exemplary aspect.

In the tracker module 100B according to the current exemplary aspect, the power inductor L71 is not disposed adjacent to the integrated circuit 80. In a plan view of the module laminate 90, the capacitors C61 to C64 are disposed between the power inductor L71 and the integrated circuit 80.

The tracker module 100B includes a metal member 93B instead of the metal member 93A. Like the metal member 93A, the metal member 93B is disposed on the main surface 90a of the module laminate 90 and protrudes from the main surface 90a. Thus, at least a part of the metal member 93B is present above the main surface 90a. In the current exemplary aspect, the metal member 93B is a metal wall that protrudes from the main surface 90a and that extends along the y axis and is disposed adjacent to the power inductor L71. In a plan view of the module laminate 90, the metal member 93B is disposed between the power inductor L71 and each of the inductors L51A to L53A and L51B to L53B included in the filter circuits 40A and 40B.

The metal member 93B is in contact with the shield electrode layer 92 on an upper surface of the tracker module 100B and furthermore, is in contact with the shield electrode layer 92 on side surfaces of the tracker module 100B. Accordingly, the metal member 93B can form a boundary between a region in which the power inductor L71 is disposed on the main surface 90a and a region in which the filter circuits 40A and 40B are disposed on the main surface 90a.

### [5.2 Effect and Like]

As described above, in the tracker module 100B according to the current exemplary aspect, the integrated circuit 80 and the power inductor L71 are disposed on the main surface 90a of the module laminate 90. The tracker module 100B further includes the inductor L51A disposed on the main surface 90a of the module laminate 90, and the metal member 93B disposed on the main surface 90a of the module laminate 90. The supply modulator 30A can output at least one of the plurality of second voltages through the filter circuit 40A including the inductor L51A. The metal member 93B is disposed between the power inductor L71 and the inductor L51A in a plan view of the module laminate 90.

According to this configuration, since the metal member 93B is disposed between the power inductor L71 and the inductor L51A, magnetic field coupling between the power inductor L71 and the inductor L51A is suppressed.

In addition, for example, in the tracker module 100B according to the exemplary aspect, the metal member 93B can be a ground electrode connected to the ground.

According to this configuration, magnetic field coupling between the power inductor L71 and the inductor L51A is more effectively suppressed.

In addition, for example, in the tracker module 100B according to the current exemplary aspect, the metal member 93B may be in contact with the shield electrode layer 92 on the upper surface and the side surfaces of the tracker module 100B.

According to this configuration, a gap between the metal member 93B and the upper surface and the side surfaces of the tracker module 100B can be closed, and a boundary can be formed between the region in which the power inductor L71 is disposed on the main surface 90a and the region in which the inductor L51A is disposed on the main surface 90a. Furthermore, the ground potential of the metal member 93B is further stabilized. Consequently, magnetic field coupling between the power inductor L71 and the inductor L51A is more effectively suppressed.

According to an exemplary aspect, the tracker module 100B does not include the metal member 93B, like the tracker module 100 according to Example 1. Even in this case, deterioration of characteristics and EMI caused by noise is suppressed by disposing the power inductor L71 on the same module laminate 90 as the integrated circuit 80.

### Example 4

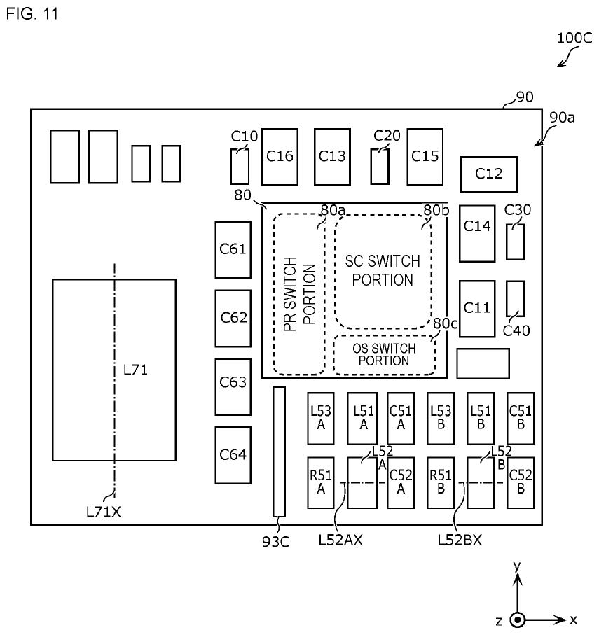

Next, a fourth exemplary aspect (Example 4) of the power supply circuit 1 will be described. The current exemplary aspect is mainly different from Example 3 in that the metal member is closer to the filter circuit than the power inductor is. Hereinafter, a tracker module 100C according to the current exemplary aspect will be mainly described with reference to FIG. 11, based on its differences from Example 3.

### [6.1 Component Disposition of Tracker Module 100C]

FIG. 11 is a plan view of the tracker module 100C according to the current exemplary aspect. In FIG. 11, the resin member 91 and the shield electrode layer 92 are not illustrated. In addition, in FIG. 11, a block without a reference numeral indicates any circuit component that may be omitted in an alternative exemplary aspect.

The tracker module 100C according to the current exemplary aspect includes a metal member 93C instead of the metal member 93B. The metal member 93C is a metal wall extending along the y axis. In a plan view of the module laminate 90, the metal member 93C is disposed between the power inductor L71 and each of the inductors L51A to L53A and L51B to L53B included in the filter circuits 40A and 40B.

In the current exemplary aspect, the metal member 93C is disposed adjacent to at least a part of the filter circuit 40A. Conversely, the metal member 93C is not disposed adjacent to the power inductor L71. That is, in the exemplary aspect, the metal member 93C is closer to the filter circuit 40A than the power inductor L71 is.

### [6.2 Effect and Like]

As described above, in the tracker module 100C according to the current exemplary aspect, the integrated circuit 80 and the power inductor L71 are disposed on the main surface 90a of the module laminate 90. The tracker module 100C further includes the inductor L51A disposed on the main surface 90a of the module laminate 90, and the metal member 93C disposed on the main surface 90a of the module laminate 90. The supply modulator 30A can output at least one of the plurality of second voltages through the filter circuit 40A including the inductor L51A. The metal member 93C is disposed between the power inductor L71 and the inductor L51A in a plan view of the module laminate 90.

According to this configuration, since the metal member 93C is disposed between the power inductor L71 and the inductor L51A, magnetic field coupling between the power inductor L71 and the inductor L51A is suppressed.

In addition, for example, in the tracker module 100C according to the exemplary aspect, the metal member 93C may be a ground electrode connected to the ground.

According to this configuration, magnetic field coupling between the power inductor L71 and the inductor L51A is more effectively suppressed.

### Example 5

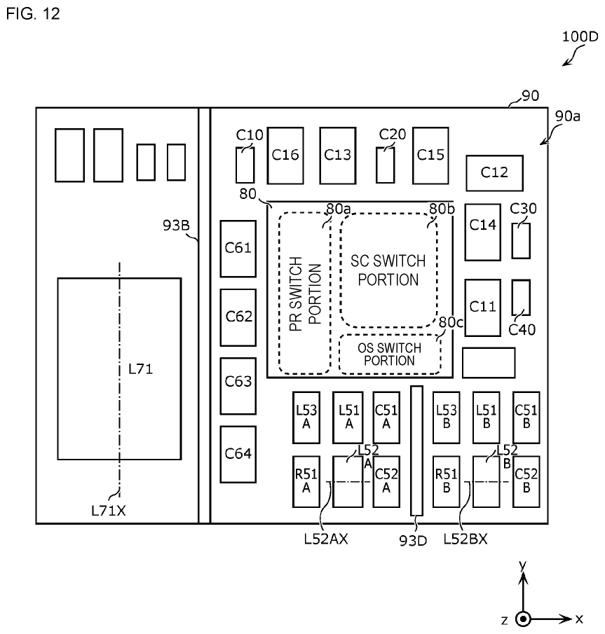

Next, a fifth exemplary aspect (Example 5) of the power supply circuit 1 will be described. The current exemplary aspect is mainly different from Example 3 in that a metal member is disposed between the two filter circuits. Hereinafter, a tracker module 100D according to the current exemplary aspect will be mainly described with reference to FIG. 12, based on its differences from Example 3.

### [7.1 Component Disposition of Tracker Module 100D]

FIG. 12 is a plan view of the tracker module 100D according to the current exemplary aspect. In FIG. 12, the resin member 91 and the shield electrode layer 92 are not illustrated. In addition, in FIG. 12, a block without a reference numeral indicates any circuit component that may be omitted in an alternative exemplary aspect.

The tracker module 100D according to the current exemplary aspect includes a metal member 93D in addition to the metal member 93B. The metal member 93D is a metal wall extending along the y axis. The metal member 93D is disposed between the filter circuits 40A and 40B in plan view of the module laminate 90. That is, in plan view of the module laminate 90, the metal member 93D is disposed between the inductors L51A to L53A and the inductors L51B to L53B.

### [7.2 Effect and Like]

As described above, the tracker module 100D according to the current exemplary aspect includes the inductors L51A and L51B disposed on the main surface 90a of the module laminate 90, and the metal member 93D disposed on the main surface 90a of the module laminate 90. The supply modulator 30A can output at least one of the plurality of second voltages through the filter circuit 40A including the inductor L51A. The supply modulator 30B can output at least one of the plurality of second voltages through the filter circuit 40B including the inductor L51B. The metal member 93D is disposed between the inductors L51A and L51B in plan view of the module laminate 90.

According to this configuration, magnetic field coupling between the inductors L51A and L51B is suppressed. Accordingly, when the power supply voltages V_{ETA} and V_{ETB} are supplied to the two power amplifiers 2A and 2B at the same time, interference between the power supply voltages V_{ETA} and V_{ET} is suppressed, and noise is reduced.

### Additional Exemplary Embodiments

While the tracker module according to the exemplary aspects of the present disclosure has been described above based on the embodiment and the examples, the tracker module according is not limited to the embodiment or the examples. For example, the exemplary aspects of the present invention also includes other embodiments and other examples implemented by combining any constituents in the embodiment and the examples, modification examples obtained by carrying out various modifications perceived by those skilled in the art to the embodiment and the examples without departing from the gist of the present invention, and various devices incorporating the tracker module.

For example, in the circuit configurations of various circuits according to the embodiment, other circuit elements, wires, and the like may be provided on the paths connecting each circuit element and the signal paths disclosed in the drawings. For example, an impedance matching circuit may be provided between the power amplifier 2A and the filter 3A and/or between the filter 3A and the antenna 6.

In addition, for example, in the tracker module 100 according to the exemplary aspects, the capacitor C51A and/or C52A may be included in the integrated circuit 80. In addition, the capacitor C51B and/or C52B may be included in the integrated circuit 80. This can contribute to size reduction of the tracker module 100.

While the pre-regulator circuit 10 includes one power inductor L71 in the embodiment, the pre-regulator circuit 10 may include a plurality of power inductors. In this case, at least one of the plurality of power inductors may be disposed on the module laminate 90 to be included in the tracker module.

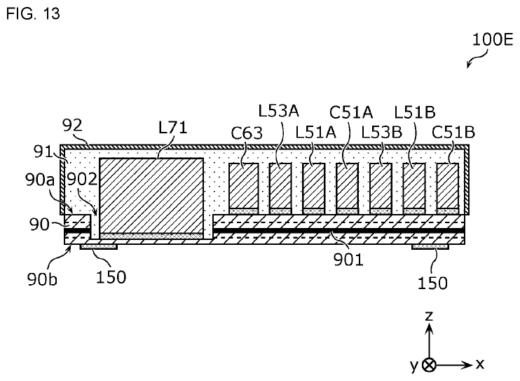

In each of the examples, for example, as illustrated in FIG. 13, the power inductor L71 may be disposed in a cavity 902 formed in the module laminate 90. FIG. 13 is a sectional view of a tracker module 100E according to another example. The cavity 902 is a recessed portion formed on the main surface 90a of the module laminate 90. In FIG. 13, a part of the power inductor L71 is provided in the cavity 902. According to this configuration, the height of the power inductor L71 from the main surface 90a can be set close to heights of other circuit components disposed on the main surface 90a, and height reduction of the tracker module 100E is achieved.

The exemplary aspects of the present disclosure can be widely used for communication devices such as a mobile phone as a tracker module that supplies a power supply voltage to a power amplifier.

### REFERENCE SIGNS LIST

1 POWER SUPPLY CIRCUIT
2A, 2B POWER AMPLIFIER
3A, 3B FILTER
4 PA CONTROL CIRCUIT
5 RFIC
6 ANTENNA
7 COMMUNICATION DEVICE
10 PRE-REGULATOR CIRCUIT
20 SWITCHED-CAPACITOR CIRCUIT
30A, 30B SUPPLY MODULATOR
40A, 40B FILTER CIRCUIT
50 DIRECT CURRENT POWER SOURCE
80 INTEGRATED CIRCUIT
80A PR SWITCH PORTION
80B SC SWITCH PORTION
80C OS SWITCH PORTION
90 MODULE LAMINATE
90A, 90B MAIN SURFACE
91 RESIN MEMBER
92 SHIELD ELECTRODE LAYER
93A, 93B, 93C, 93D METAL MEMBER
100, 100A, 100B, 100C, 100D, 100E TRACKER MODULE
110, 131A, 131B, 132A, 132B, 133A, 133B, 134A, 134B, 140A, 140B INPUT TERMINAL
111, 112, 113, 114, 130A, 130B, 141A, 141B OUTPUT TERMINAL
117, 120, 135A, 135B, 136A, 136B CONTROL TERMINAL
150 LAND ELECTRODE
901 GROUND PLANE
902 CAVITY
C10, C11, C12, C13, C14, C15, C16, C20, C30, C40, C51A, C51B, C52A, C52B, C61, C62, C63, C64 CAPACITOR
L51A, L51B, L52A, L52B, L53A, L53B INDUCTOR
L51AX, L51BX, L52AX, L52BX, L53AX, L53BX, L71X WINDING AXIS
L71 POWER INDUCTOR
N1, N2, N3, N4 NODE
R51A, R51B RESISTOR
S11, S12, S13, S14, S21, S22, S23, S24, S31, S32, S33, S34, S41, S42, S43, S44, S51A, S51B, S52A, S52B, S53A, S53B, S54A, S54B, S61, S62, S63, S71, S72 SWITCH
V1, V2, V3, V4 VOLTAGE

1. A tracker module comprising:
a module laminate;
a power inductor on the module laminate; and
at least one integrated circuit on the module laminate and including:
at least one switch included in a pre-regulator circuit that is configured to convert an input voltage into a first voltage using the power inductor,
at least one switch included in a switched-capacitor circuit that is configured to generate a plurality of discrete voltages based on the first voltage, and
at least one switch included in a supply modulator that configured to selectively output at least one of the plurality of discrete voltages based on an envelope signal.

2. The tracker module according to claim 1, wherein the power inductor is disposed adjacent to the at least one integrated circuit on the module laminate.

3. The tracker module according to claim 1, wherein the at least one integrated circuit includes:
a first switch portion including the at least one switch included in the pre-regulator circuit,
a second switch portion including the at least one switch included in the switched-capacitor circuit, and
a third switch portion including the at least one switch included in the supply modulator,
wherein the first switch portion is disposed closer to the power inductor than both the second switch portion and the third switch portion.

4. The tracker module according to claim 1, further comprising:
an inductor included in a filter circuit and disposed on the module laminate; and
a circuit component disposed on the module laminate,
wherein the supply modulator is further configured to selectively output the at least one discrete voltage through the filter circuit, and
wherein the circuit component is disposed between the power inductor and the inductor of the filter circuit in a plan view of the module laminate.

5. The tracker module according to claim 1, wherein:
the at least one integrated circuit and the power inductor are disposed on a main surface of the module laminate,
wherein the tracker module further includes:
an inductor included in a filter circuit and disposed on the main surface of the module laminate, and
a metal member disposed on the main surface of the module laminate,
wherein the supply modulator is further configured to selectively output the at least one discrete voltage through the filter circuit, and
wherein the metal member is disposed between the power inductor and the inductor of the filter circuit in a plan view of the module laminate.

6. The tracker module according to claim 5, wherein the metal member is a ground electrode.

7. The tracker module according to claim 4, wherein a winding axis of a coil of the power inductor is perpendicular to a winding axis of a coil of the inductor of the filter circuit.

8. The tracker module according to claim 1, further comprising:
a resin member that covers at least a part of a main surface of the module laminate and at least a part of a circuit component on the main surface; and
a metal layer that covers at least a part of a surface of the resin member.

9. The tracker module according to claim 1, wherein the module laminate includes a cavity, and at least a part of the power inductor is disposed in the cavity.

10. A tracker module comprising:
a module laminate;
a power inductor on the module laminate; and
at least one integrated circuit on the module laminate and including:
at least one switch included in a pre-regulator circuit that is configured to convert an input voltage into a first voltage using the power inductor,
at least one switch included in a switched-capacitor circuit that is configured to generate a plurality of discrete voltages based on the first voltage, and
at least one switch included in a supply modulator that includes a control terminal connected to a control circuit and that is configured to selectively output at least one of the plurality of discrete voltages.

11. The tracker module according to claim 10, further comprising:
an inductor included in a filter circuit and disposed on the module laminate; and
a circuit component disposed on the module laminate,
wherein the supply modulator is further configured to selectively output the at least one discrete voltage through the filter circuit, and
wherein the circuit component is disposed between the power inductor and the inductor of the filter circuit in a plan view of the module laminate.

12. A tracker module comprising:
a module laminate;
a power inductor on the module laminate; and
at least one integrated circuit on the module laminate and including:
at least one switch included in a pre-regulator circuit,
at least one switch included in a switched-capacitor circuit that includes:
a first capacitor including a first electrode and a second electrode, and
a second capacitor including a third electrode and a fourth electrode, and
at least one switch included in a supply modulator that includes an output terminal,
wherein the at least one switch included in the switched-capacitor circuit includes a first switch, a second switch, a third switch, a fourth switch, a fifth switch, a sixth switch, a seventh switch, and an eighth switch,
wherein:
a first end of the first switch and a first end of the third switch are connected to the first electrode,
a first end of the second switch and a first end of the fourth switch are connected to the second electrode,
a first end of the fifth switch and a first end of the seventh switch are connected to the third electrode,
a first end of the sixth switch and a first end of the eighth switch are connected to the fourth electrode,
a second end of the first switch, a second end of the second switch, a second end of the fifth switch, and a second end of the sixth switch are connected to each other,
a second end of the third switch is connected to a second end of the seventh switch,
a second end of the fourth switch is connected to a second end of the eighth switch,
wherein the at least one switch included in the supply modulator includes:
a ninth switch connected between the output terminal and the second end of the first switch, the second end of the second switch, the second end of the fifth switch, and the second end of the sixth switch, and
a tenth switch connected between the output terminal and the second ends of the third switch and the seventh switch,
wherein the pre-regulator circuit includes the power inductor and an input terminal, and the at least one switch included in the pre-regulator circuit includes:
an eleventh switch connected between the input terminal and a first end of the power inductor, and
a twelfth switch connected between the first end of the power inductor and a ground, and
wherein a second end of the power inductor is connected to the respective second ends of the first switch, the second switch, the fifth switch, and the sixth switch.

13. The tracker module according to claim 12, wherein the power inductor is disposed adjacent to the at least one integrated circuit on the module laminate.

14. The tracker module according to claim 12, wherein the at least one integrated circuit includes:
a first switch portion including the at least one switch included in the pre-regulator circuit,
a second switch portion including the at least one switch included in the switched-capacitor circuit, and
a third switch portion including the at least one switch included in the supply modulator, and
wherein the first switch portion is disposed closer to the power inductor than both the second switch portion and the third switch portion.

15. The tracker module according to claim 12, further comprising:
an inductor included in a filter circuit and disposed on the module laminate; and
a circuit component disposed on the module laminate,
wherein the output terminal of the supply modulator is connected to an input terminal of the filter circuit, and
wherein the circuit component is disposed between the power inductor and the inductor of the filter circuit in a plan view of the module laminate.

16. The tracker module according to claim 12, wherein:
the at least one integrated circuit and the power inductor are disposed on a main surface of the module laminate,
the tracker module further includes:
an inductor included in a filter circuit and disposed on the main surface of the module laminate, and
a metal member disposed on the main surface of the module laminate,
the output terminal of the supply modulator is connected to an input terminal of the filter circuit, and
the metal member is disposed between the power inductor and the inductor of the filter circuit in a plan view of the module laminate.

17. The tracker module according to claim 16, wherein the metal member is a ground electrode.

18. The tracker module according to claim 15, wherein a winding axis of a coil of the power inductor is perpendicular to a winding axis of a coil of the inductor of the filter circuit.

19. The tracker module according to claim 12, further comprising:
a resin member that covers at least a part of a main surface of the module laminate and at least a part of a circuit component on the main surface; and
a metal layer that covers at least a part of a surface of the resin member.

20. The tracker module according to claim 12, wherein the module laminate includes a cavity and at least a part of the power inductor is disposed in the cavity.
